(19) United States
(12) Patent Application Publication
(10) Pub. No.: US 2006/0103398 A1
(43) Pub. Date: May 18, 2006

(54) Systems and methods for etching and plating probe cards

(75) Inventor: Hsu Ming Cheng, Hsin-Chu (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: Taiwan Semiconductor Manufacturing Company, Ltd.

(21) Appl. No.: 10/978,709

(22) Filed: Nov. 1, 2004

(51) Int. Cl. G01R 31/02

(52) U.S. Cl. 324/754

(57) ABSTRACT

Systems and methods for etching probe cards are described. In particular, a fixture device is used in facilitating an electrical charge to the base of probe card needles during etching of the probe card needles. The fixture device includes an electrically conductive base having an electrically conductive rod and a plurality of electrically conductive pins extending from the base. The electrically conductive rod receives negative voltage from a power supply to transmit electricity through the base and through the plurality of pins. A probe card is placed in proximity to the fixture device such that the needles of the probe card come in contact with the plurality of pins. An etching brush connected to a positive voltage source of the power supply is then used to etch the probe card needles, thereby completing the circuit. Related systems and methods for performing plating operations on probe cards are also described.

### TECHNICAL FIELD

Disclosed embodiments herein relate generally to testing of semiconductor devices, and more particularly to devices and systems, which when implemented, improve etching and plating operations associated with the testing of semiconductor devices. Related methods of performing etching and plating operations are also described.

### BACKGROUND

Semiconductor wafer processes generally begin with processes associated with fabricating a semiconductor wafer such as layering, patterning, doping, and heat treatments. Once fabricated, semiconductor wafers undergo additional processes associated with testing, packaging, and assembling semiconductor IC chips obtained from the wafers.

Semiconductor devices are manufactured to include a plurality of bonding pads, which are electrically conductive pads configured to facilitate electrical communication between the semiconductor devices and other devices associated with a particular circuit design. Testing of IC chips typically includes testing of the bonding pads to ensure that they are functioning properly. Such testing often includes the use of multi-pin probe arrays, which may come in varying forms, but generally include probe cards having a plurality of testing pins, or probe needles, and surrounding circuitry for running various tests through the probe needles.

Conventional wafer testing techniques typically position probe needles in contact with the conductive bonding pads of IC chips and tests are run through the probe needles to evaluate the functionality of the bonding pads. It has been found that etching the tips of the probe needles prior to testing can be beneficial in reducing or avoiding the formation of defects during probe card testing. Current probe needle etching methods generally include the use of a probe and a cleaning device to etch, and thereby clean, the tips of the probe needle tips. However, such processes have been found to be tedious and quite inefficient.

Additionally, some probe cards utilize testing pads, such as space transformer pads, which often wear out over time. It has been found that such pads need to be re-plated in order to function appropriately. However, current re-plating processes typically require use of a plating pen in conjunction with an electrically conductive cloth. Such re-plating processes are time-consuming, and therefore inefficient.

Therefore, improved devices and systems for etching probe needles and plating probe cards are needed, which when utilized, improve the efficiency of such processes. Related methods for performing etching and plating are also desired.

### BRIEF SUMMARY

The present disclosure relates to improved systems and methods for etching probe card needles and performing plating operations on probe cards. In one embodiment, a fixture plate is provided for supplying an electrical charge to a probe card. The fixture plate generally includes an electrically conductive extension element for receiving a positive charge from a power supply, an aluminum base portion in electrical communication with the extension element, and a plurality of pogo pins extending from the base portion operable to contact with channel pads formed on an underside of an adjacent probe card. In practice, the probe card is securely placed adjacent to the fixture plate, such as via latches extending from the fixture plate. The probe card includes testing needles, which are charged through electrical contact with the fixture plate. Accordingly, an operator need not charge the testing needles during etching thereof. Related methods for etching the needles of the probe card are also described.

In another embodiment, the fixture plate may be utilized in plating operations. In this example, a probe card having an electrical pad, such as a space-transformer pad, is securely placed adjacent to the fixture plate, thereby positively charging the electrical pad. As such, plating operations may be carried out without an operator having to charge the electrical pad during plating. Related methods for plating probe cards are also described.

### BRIEF DESCRIPTION OF THE DRAWINGS

Reference is now made to the following descriptions taken in conjunction with the accompanying drawings.

FIG. 1 illustrates a block diagram of an exemplary process associated with manufacturing semiconductor devices;

FIG. 2A illustrates a plan view of an exemplary probe card used in testing semiconductor devices;

FIG. 2B illustrates a bottom view of the exemplary probe card of FIG. 2A to shown an underside of the probe card;

FIG. 3A illustrates a schematic view of a testing bed associated with the probe card of FIG. 2A;

FIG. 3B illustrates a schematic view of a probe needle housed in the testing bed of FIG. 3A;

FIG. 4A illustrates a bonding pad having been tested with probe card needles that had not been etched prior to use;

FIG. 4B illustrates a bonding pad having been tested with probe card needles that had been etched prior to use;

FIG. 5 illustrates a schematic view of a prior art system for etching probe card needles;

FIG. 6 illustrates a perspective view of an exemplary fixture plate for use in etching probe needles according to one embodiment of the present disclosure;

FIG. 7A illustrates the exemplary fixture plate in use during etching of probe needles of the exemplary probe card;

FIG. 7B illustrates the schematic view of the testing bed associated with the exemplary probe card;

FIG. 7C illustrates the schematic view of the probe needle housed in the testing bed of the exemplary probe card;

FIG. 8 illustrates a plan view of another exemplary probe card used in semiconductor testing devices; and

FIG. 9 illustrates a perspective view of the exemplary fixture plate in use during plating of a testing pad of the exemplary probe card of FIG. 8.

### DETAILED DESCRIPTION

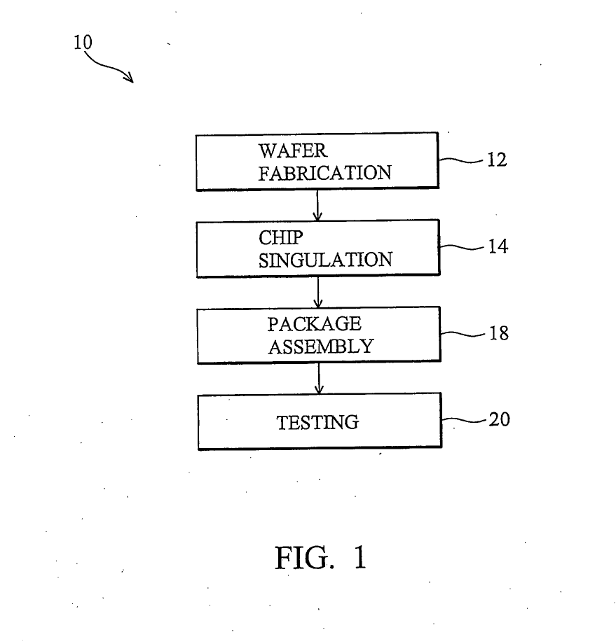

FIG. 1 illustrates an exemplary semiconductor manufacturing process 10 associated with producing IC chips for use in semiconductor applications. The process 10 includes wafer fabrication 12, which generally involves layering, patterning, doping, and applying heat treatments to a silicon wafer. The process 10 further includes singulating 14 a semiconductor wafer into a plurality of individual IC chips, each comprising an entire integrated circuit. After singulation, each chip is assembled 18 into a desired packaging, which generally provides mechanical and environmental protection for the chip and facilitates electrical interconnection with outside circuitry. Chip packages vary widely in design and may include ceramic substrates, printed circuit boards, and carriers. After assembly 18 into packaging, the singulated chips undergo testing 20 to ensure that they meet their design specifications. Although not shown, there are various other processes associated with the manufacture of semiconductor devices. Additionally, semiconductor devices may undergo testing at various times throughout the manufacturing process 10, and therefore, the testing 20 after packing the semiconductor device is merely one example of when a testing procedure may take place during semiconductor manufacturing.

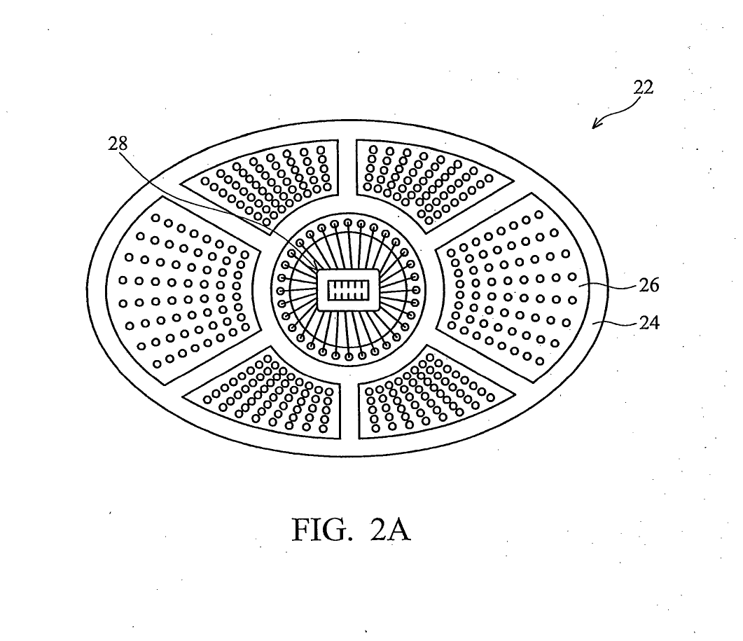

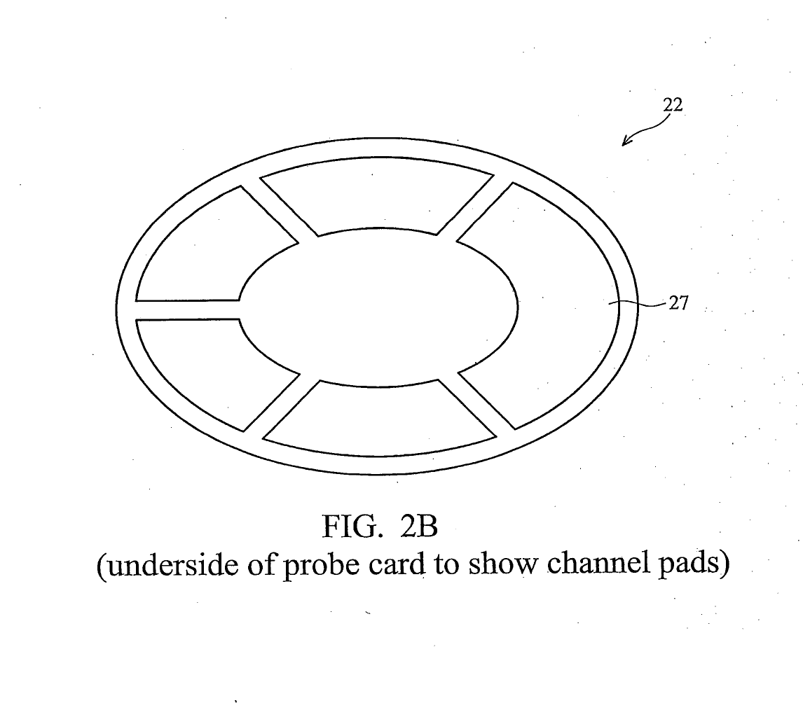

Testing of semiconductor devices often includes the use of probe cards, which are used to conduct various electronic tests on semiconductor devices. FIG. 2A illustrates an exemplary probe card 22 comprising a PCB board 24 having a plurality of circuit sections 26 formed on it, and a testing bed 28 disposed at approximately the geometrical center of the probe card 22. The circuit sections 26 are generally associated with a plurality of circuits for testing semiconductor devices as will be further described. The circuit sections 26 correspond to a plurality of channel pads 27 formed on an underside of the probe card 22 as illustrated in FIG. 2B. The circuit sections 26 are in electrical communication with the channel pads 27 for reasons to be described. Referring again to FIG. 2A, the testing bed 28 is generally designed to receive semiconductor devices, such as packaged IC chips, such that tests may be performed on the semiconductor devices. To facilitate such testing, some testing beds, such as the testing bed 28, often include a plurality of probe needles, which are in electrical communication with the surrounding circuitry 26 of the probe card 22. Accordingly, placement of an IC chip on the testing bed 28 effectively establishes electrical communication between the IC chip and the probe card 22. In practice, tests are run through the plurality of circuits 26, the probe needles, and the IC chip, and the functionality of the IC chip is then evaluated based on the outcomes of such tests.

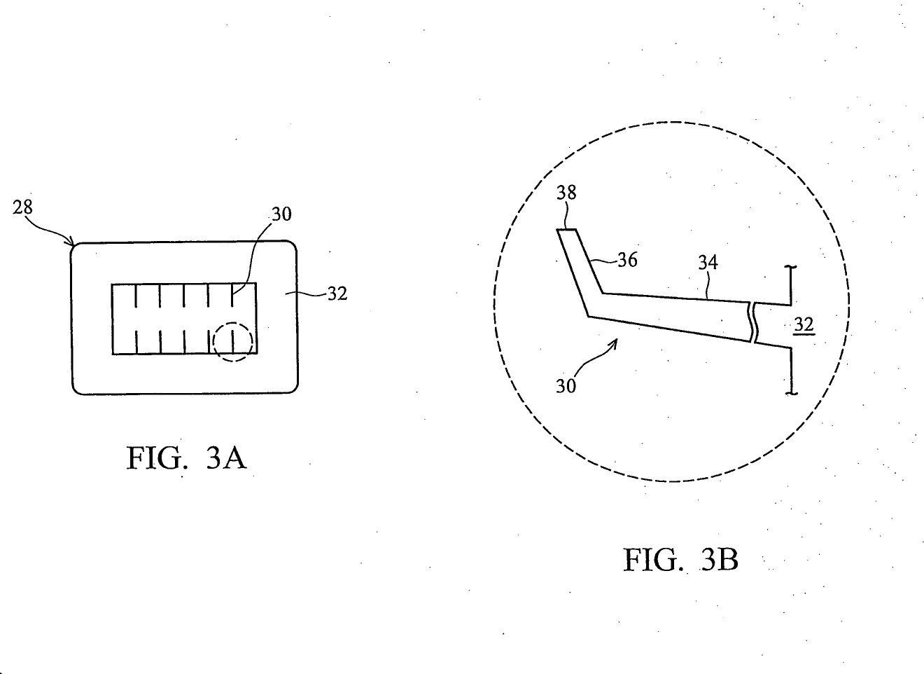

FIG. 3A schematically illustrates the testing bed 28 as having a plurality of probe needles 30 surrounded by a housing 32. In one embodiment, the housing 32 is formed of a ceramic material. For the sake of clarity, only a few probe card needles 30 are shown; however, test beds typically incorporate a large number of probe needles, typically on the order of hundreds of probe needles. In one embodiment, the testing bed 28 may accommodate 780 probe needles. FIG. 3B illustrates an exemplary probe card needle 30 having a base portion 34 extending from the housing 32, and a tip portion 36 extending from the base portion. In the example shown, the tip portion 36 extends substantially orthogonally relative to the base portion 34, thereby providing a needle tip 38 for contacting a corresponding portion of an IC chip (not shown).

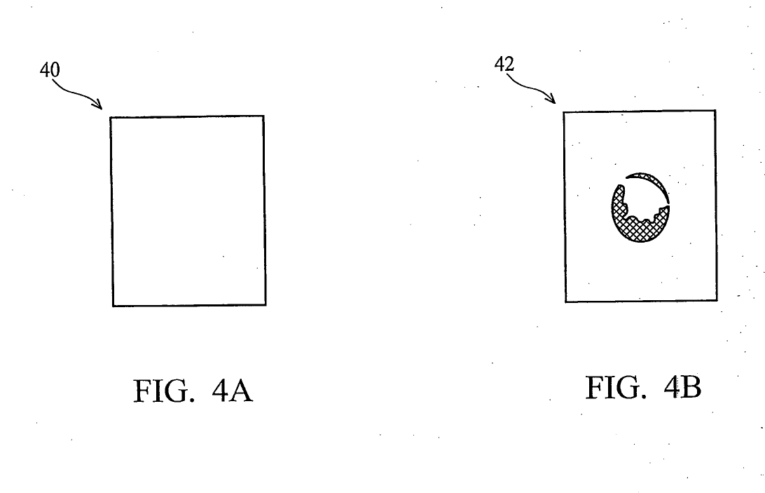

As discussed above, it is desirable to etch the tips 38 of the probe needles 30 prior to use of the probe needles in testing semiconductor devices in order to avoid, or at least reduce, the formation of defects on such semiconductor devices. FIG. 4A illustrates a bonding pad 40 of an IC chip, which has been tested with probe card needles that have not been etched prior to use. In contrast, FIG. 4B, illustrates a bonding pad 42, which has undergone testing with probe card needles that had been etched prior to use. As can be seen, defects such as pad voids (e.g. regions of the bonding pad unable to facilitate electrical communication) are much more pronounced and prevalent with the bonding pad 40 as compared with the bonding pad 42. Accordingly, the bonding pad 42 has better bondability than the bonding pad 40, and therefore, reaps benefits associated with having been tested with etched probe card needles.

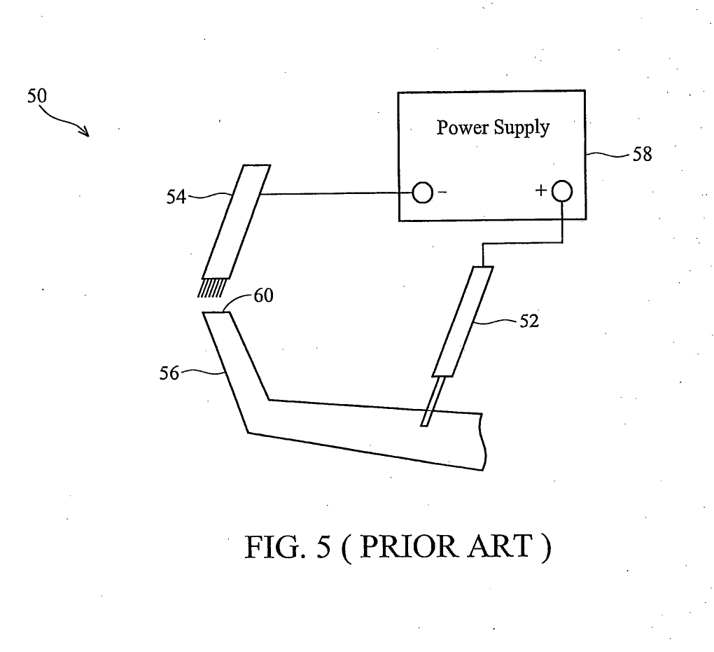

FIG. 5 illustrates a common prior art etching system 50, which includes the use of a stick probe 52 and a brush 54 for etching a probe needle 56. The stick probe 52 is connected with a power supply 58, which typically provides a positive polarity to the stick probe. For example, the power supply 58 may generate +5V through the stick probe 52. The brush 54, which includes an electrolyte, is also connected to the power supply 58, but is provided with a negative polarity in order to complete a circuit running from the power supply, through the stick probe 52, through the probe needle 56, through the brush 54, and back to the power supply 58. In this manner, the brush 54 can be used to electrically etch a tip 60 of the probe needle 56. However, the etching process associated with the etching system 50 is tedious in that it requires an operator to hold each of the stick probe 52 and the brush 54 during etching and to manually move the stick probe and brush to each individual probe needle to be etched. As such, the etching process associated with the etching system 50 is overly time consuming, and therefore inefficient, especially in view of conventional probe cards having hundreds or thousands of individual probe needles.

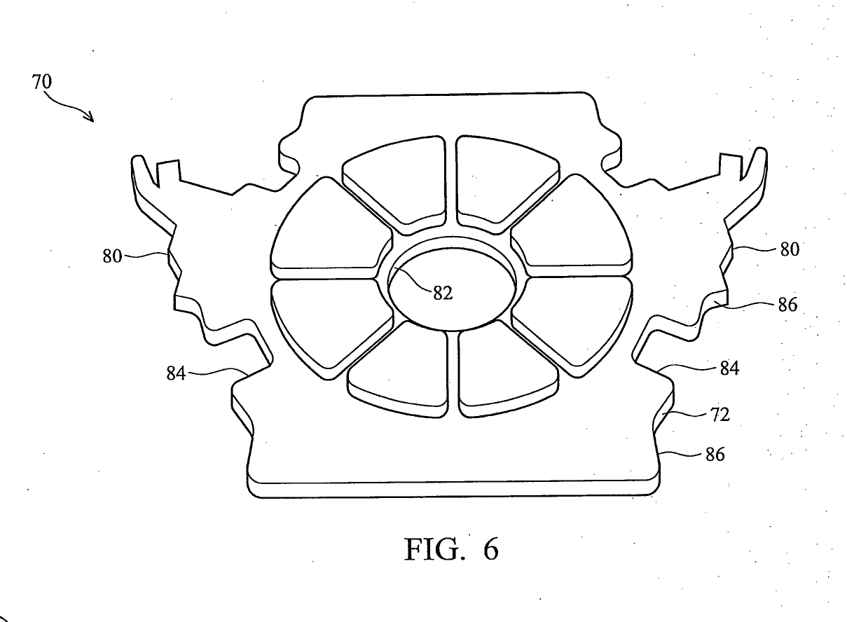

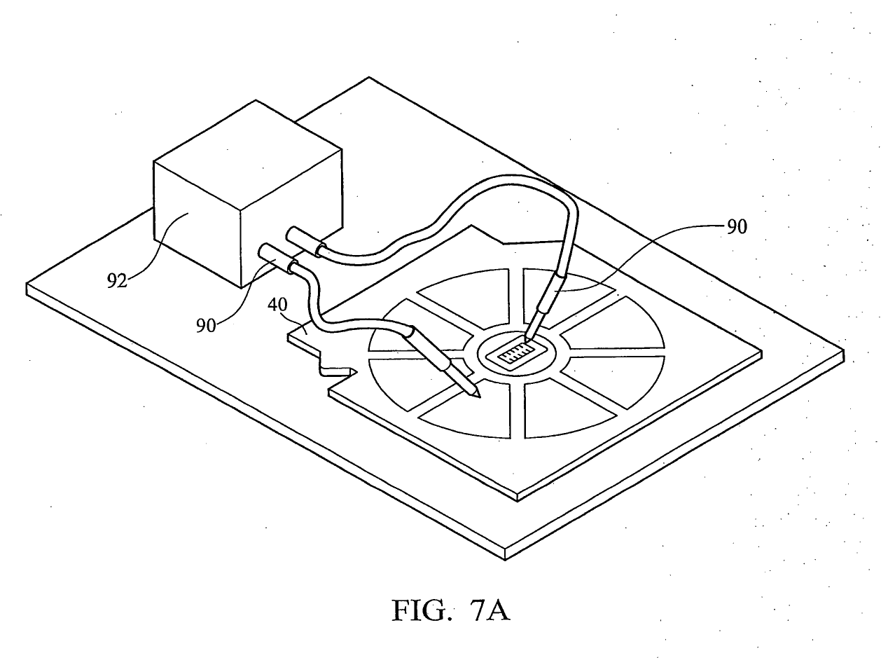

FIG. 6 illustrates a fixture device 70 for use in semiconductor manufacturing processes. In one example, the fixture device 70 may be used in etching processes associated with etching the probe card needles 30 of probe card 22 (FIG. 3). In the etching context, the fixture device 70 is generally provided for streamlining the etching process by eliminating the requirement that an operator connect a circuit through each base portion 34 of each probe card needle 30. For example, the fixture device 70 renders use of the stick probe in the prior art process of FIG. 5 unnecessary. More particularly, the fixture device 70 is designed to provide an electrical charge (e.g. negative charge) to, or facilitate an electrical charge through, the circuitry of the probe card 22, and therefore, the base portions 34 of the probe needles 30, which are in electrical communication with the circuitry. In some embodiments, the fixture device 70 will provide a constant electrical charge to the base portions 34 of the probe needles 30, thereby merely requiring an operator to use a brush to electrically etch the tips 38 of the probe needles.

The fixture device 70 includes a base 72, which in one embodiment is formed of an electrically conductive metal, such as aluminum. The fixture device 70 further includes a plurality of pin sections 74, each section being associated with a plurality of conductive pins 76 (e.g. pogo pins) extending from the base 72. The pin sections 74 are generally configured to correspond to the circuit sections 26 (FIG. 2) of the probe card 22 as will be further described. An electrically conductive element 78 (e.g., a rod) extends from the aluminum base 72 and is provided to receive voltage from a power source (not shown). In practice, the fixture device 70 is to be used in proximity to the probe card 22, and therefore, includes a pair of securing elements 80 disposed on opposing sides of the fixture device. In one embodiment, the securing elements 80 take the form of a pair of latches, which when engaged, operate to secure the probe card 22 to the fixture device. Although described in an exemplary embodiment as being a pair of latches, the securing elements 80 may comprise any device operable to retain the probe card 22 in proximity to the fixture device 70.

As shown, the fixture device 70 includes other characteristics such as a bore 82 disposed through a geometrical center of the fixture plate. The bore 82 saves costs associated with manufacturing the fixture device 70 as well as provides an access path to an underside of a probe card during testing of the probe card. The fixture device 70 additionally includes a non-uniform profile when viewed from the plan perspective. For example, a pair of indentations 84 are formed in opposing sides of the fixture device 70 to allow for improved ergonomic handling of the fixture device. Of course, the perimeter of the fixture device 70 may take a variety of other configurations to improve the ergonomics of the fixture device. The fixture device 70 may also include a plurality of connectors 86 for securing the fixture device 70 to another device or to a workstation surface.

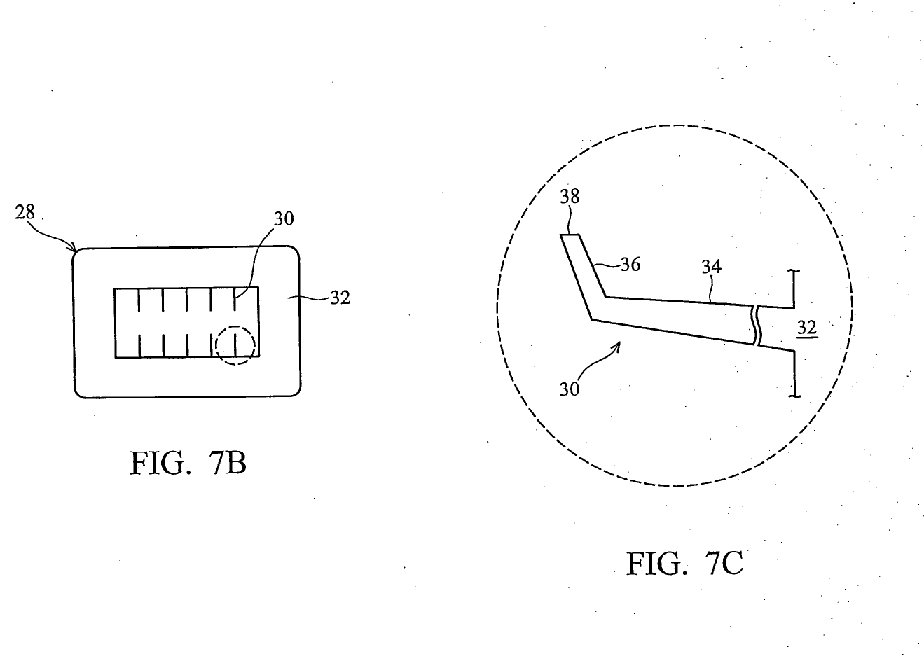

FIG. 7A illustrates the probe card 22 secured to the fixture device 70 via the securing elements 80, and FIGS. 7B and 7C illustrate magnified views of the testing bed 28 and the probe needles 30. FIGS. 7B and 7C are identical to FIGS. 3A and 3B, but are re-presented in connection with FIG. 7A for the sake of clarity. As discussed previously, the probe card 22 includes the plurality of channel pads 27 (see FIG. 2B) corresponding to the circuitry 26 associated with the probe card 22. The channel pads 27 are formed on the underside of the probe card 22 such that when the probe card is placed in the securing elements 80, the electrically conductive pins 76 (see FIG. 6) of the fixture device 70 come in contact with the channel pads 27. The channel pads (not shown) are in parallel communication with the probe needles 30, and thus, an electrical charge provided through the electrically conductive pins essentially shorts the channel pads together such that the electrical charge can simultaneously arrive to the base portions 34 of the probe needles 30. By providing an electrical charge conjunctively to the base portions 34, an operator need only use a brush 90 to complete the electrical circuit and etch the tips 38 of the probe card needles 30, thereby streamlining the etching process. The brush 90 may be operable to emit an etching liquid for use in the etching processes. The etching liquid may include an electrolyte, such as sodium hydroxide (NaOH) or potassium hydroxide (KOH), mixed with an amount of de-ionized (DI) water. In one example, the etching liquid may be mixed to include a certain ratio of electrolyte/DI water, such as 1 unit of NaOH for every 10 units of DI water.

In practice, the fixture device 70 and associated probe card 22 may be used with a power supply 92, which provides the electrical charge needed for etching of the needle tips 38. The power supply may be a DC or AC power source. The power supply includes a source of negative voltage 94 and a source of positive voltage 96. In one embodiment, the source of negative voltage 94 may be linked to the electrically conductive element 78 of the fixture device 70 via a wire 100. Additionally, the source of positive voltage 96 may be linked to the brush 90 via a wire 98. To accommodate the electrical connection, the brush 90 may be formed to have a metallic portion, such as a metallic ring. In one embodiment, the metallic ring may be formed of iron. In practice, both of the negative and positive voltage sources 94, 96, respectively, may be activated to complete a circuit from the power supply 92, through the fixture device 70, through the probe card 22, and back to the power supply. Etching of the needle tips 38 may then be carried out through use of the brush 90.

Use of the fixture device 70 in etching the probe card needles 30 substantially reduces the amount of time needed to perform the etching processes. Some experimental data reflects an increase in efficiency of up to 50%, thereby cutting in half the time required to perform etching processes. Such increases of efficiency translate into reductions of manpower, and ultimately savings in operating costs.

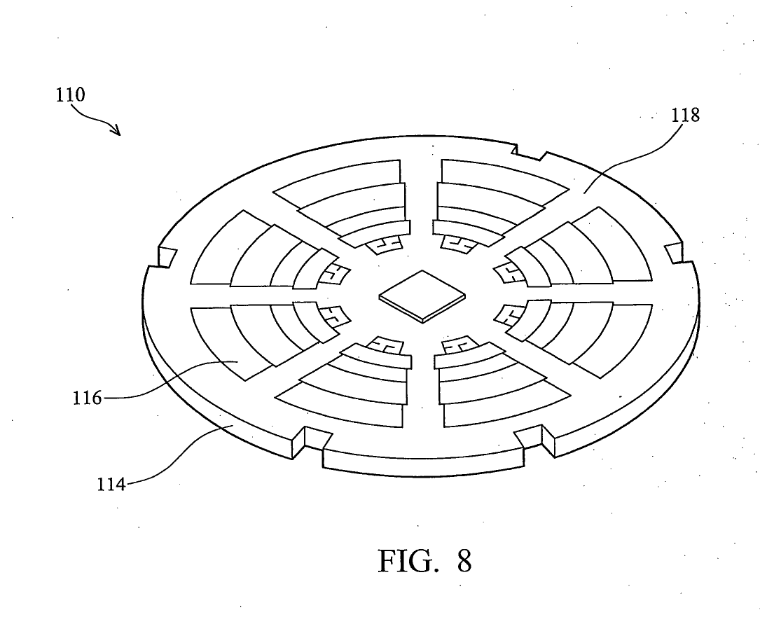

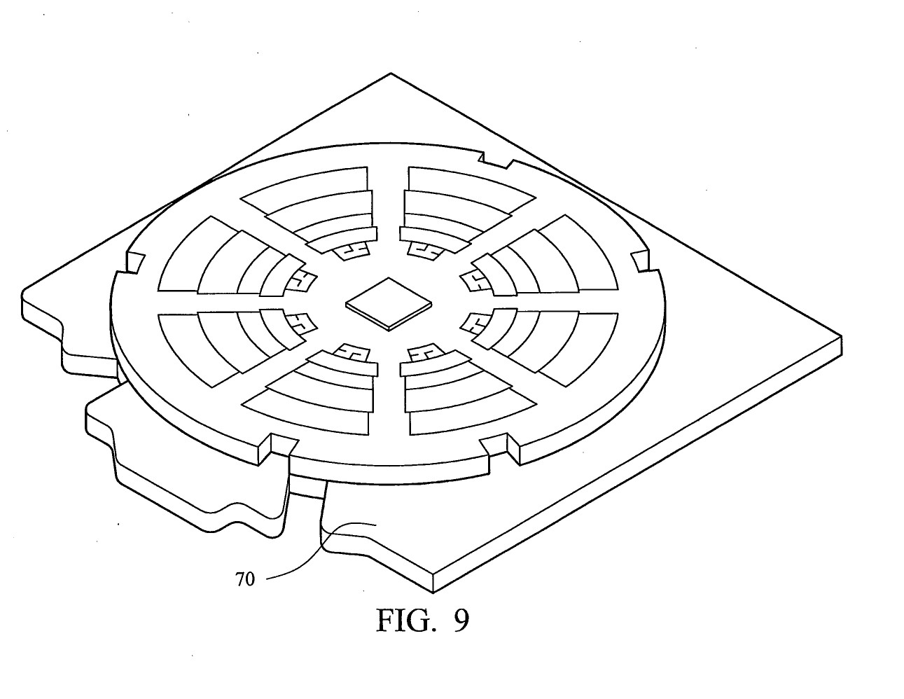

Use of the fixture device 70 is not limited to etching processes, but rather may be adapted for use into a variety of other types of semiconductor processes. For example, the fixture device 70 may be used in plating processes. Many probe cards incorporate electrically conductive pads for testing semiconductor devices, such as IC chips. For example, referring to FIG. 8, a vertical probe card 110 includes a testing pad 112, such as a space transformer (ST) pad, positioned at approximately the geometrical center of the probe card. The probe card 110 is similar to the probe card 22 in that it includes a substrate 114 forming a majority of the surface area of the probe card and a plurality of circuitry sections 116 embedded in the substrate. IC chips are typically positioned in contact with the testing pad 112 of the probe card 110, or alternatively, in contact with a testing head (not shown) positioned over the testing pad 112, to evaluate the functionality of bonding pads formed on the IC chips or to otherwise evaluate the chip operation. In practice, electrical tests are run through the testing pad 112, and if applicable, the testing head, to test the electrical performance of an IC chip. It has been found that the effectiveness (e.g. electrical performance) of the testing pad in conducting such tests deteriorates over time, typically due to the number of touchdowns (i.e. contacts) between the testing pad and associated IC chips or testing heads. Therefore, the testing pad 112 needs to be re-plated from time to time to maintain the integrity of the electrical tests.

Plating processes generally involves depositing liquid onto the surface of the testing pad 112, usually through the use of a plating pen 118, to improve the electrical performance of the testing pad. Various liquids may be used during plating processes including degreaser agents and various metallic liquids. Accordingly, some plating processes may utilize multiple plating pens. In one exemplary plating process, three plating pens may be used to re-plate the testing pad 112. More particularly, a degreaser plating pen may be used to deposit degreaser agents onto the testing pad 112 to cleanse the pad. A nickel plating pen may then be used to deposit liquid nickel onto the testing pad 112. Liquid nickel is typically used with testing pads formed of gold, as nickel facilitates gold plating. Finally, a gold plating pen may be used to deposit liquid gold onto the testing pad 112, thereby completing the plating process. The plating pen 118 typically forms a positive pole, thus requiring a negative pole to complete the electrical circuit. Conventional plating operations require the use of an electrically conductive cloth, which acts as the negative pole. Thus, when a plating pen is used in plating operations, an operator is required to move the conductive cloth to contact the corresponding channel pad on the probe card 110. Accordingly, present plating operations are inefficient, and are challenging to undertake, particularly in view of the requirement associated with constantly relocating the conductive cloth.

Referring to FIG. 9, the fixture device 70 may be used during plating operations to facilitate formation of the electrical circuit associated with the re-plating process. In particular, the probe card 110 is secured to the fixture device 70 via the securing elements 80 to place the testing pad 112 in electrical communication with the fixture device. The fixture device 70 functions similarly with the probe card 110 as it does with the probe card 22. Generally speaking, the probe card 110 is used with the power supply 92 such that an electrical circuit is created from the power supply, through the fixture device 70, through the probe card 110, through the plating pen 118, and back to the power supply 92. More particularly, the positive source of voltage 96 is connected to the plating pen 118 via wire 100, while the negative source of voltage 94 is connected to the electrically conductive element 78 via wire 98. Accordingly, the base portion 72 of the fixture plate 70 becomes charged, thereby charging channel pads (not shown) on the underside of the probe card 110. The channel pads are in parallel communication with one another such that the channel pads (and their associated circuitry sections 116) short together upon application of the electrical charge. As such, the fixture device 70 eliminates the need to continually move an electrically conductive cloth during plating operations. Accordingly, use of the fixture device 70 streamlines the plating process, thereby increasing the efficiency of performing such operations.

While various systems and methods for etching probe card needles and plating pads associated with probe cards according to the principles disclosed herein have been described above, it should be understood that they have been presented by way of example only, and not limitation. For example, the shape of the fixture device 70 may vary from that disclosed above. Accordingly, the fixture device 70 may take a variety of shapes and orientations so long as the fixture device provides or facilitates an electrical charge to the probe card needles 30 or testing pad 112. Also, the probe cards 22, 110 are merely illustrative of the types of probe cards that may be used with the fixture device 70. Accordingly, the fixture device 70 is not limited to use with the probe cards 22, 110, but rather may be used with any suitable probe card in conducting any compatible test. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A fixture device for use in testing semiconductor devices, comprising:
a base portion being formed of an electrically conductive material; and
a plurality of pin sections disposed on the base portion, each pin section having a plurality of electrically conductive pins extending from the base portion.

2. A fixture device according to claim 1 further comprising an electrically conductive element extending from the base portion, the electrically conductive element being operable to receive an electrical charge.

3. A fixture device according to claim 2 wherein the electrically conductive element is an aluminum rod.

4. A fixture device according to claim 1 wherein the plurality of electrically conductive pins are pogo pins.

5. A fixture device according to claim 2 wherein each pin section is in parallel communication with other pin sections.

6. A fixture device according to claim 5 wherein an electrical path is defined along the electrically conductive element, the base portion, and the plurality of pin sections, whereby an electrical charge supplied to the electrically conductive element causes the pin sections to short together.

7. A fixture device according to claim 1 further comprising at least two securing elements, the securing elements being operable to secure a semiconductor testing device to the fixture device.

8. A fixture device according to claim 7 wherein the at least two securing elements comprise latches.

9. A fixture device according to claim 1 wherein the base portion is formed to include a plurality of sides, and wherein at least two substantially opposing sides include a pair of grooves formed therein.

10. A fixture device according to claim 1 wherein the base portion is formed of aluminum.

11. A fixture device according to claim 1 wherein the base portion includes a bore formed through a substantially geometric center of the fixture device.

12. A system for cleaning semiconductor testing devices, comprising:
a fixture device having a base portion and plurality of electrically conductive pin sections extending from the base portion;
a probe card in electrical communication with the fixture device, the probe card having a testing bed disposed thereon;
a cleaning device for cleaning portions of the testing bed; and
a power supply operable to supply an electrical charge to the fixture device and the cleaning device.

13. A system according to claim 12 wherein contact between the cleaning device and the testing bed causes an electrical path to be defined along at least the power supply, the fixture device, the probe card, and the etching device.

14. A system according to claim 12 wherein the probe card includes a plurality of circuit sections, the circuit sections corresponding to and being in electrical communication with the plurality of pin sections of the fixture device.

15. A system according to claim 14 wherein the testing bed comprises a plurality of probe card needles, the probe card needles being in electrical communication with the plurality of circuit sections.

16. A system according to claim 12 wherein the fixture device further comprises an electrically conductive element extending therefrom, the electrically conductive element being operable to receive an electrical charge from the power supply.

17. A system according to claim 16 wherein the electrically conductive element is an aluminum rod.

18. A system according to claim 12 wherein the fixture device further comprises at least two securing elements, the securing elements being operable to secure the probe card to the fixture device.

19. A system according to claim 18 wherein the securing elements are latches.

20. A system according to claim 1.6 wherein the power supply comprises a positive source of voltage and a negative source of voltage, the positive source being connected to the cleaning device via a wire, and the negative source being connected to the electrically conductive element via a wire.

21. A system according to claim 12 wherein the cleaning device is an etching brush.

22. A system according to claim 12 wherein the cleaning device is a plating tool.

23. A method for performing etching operations on a semiconductor testing device, comprising:
providing a fixture device having a base portion, and a plurality of pin sections extending from the base portion;
disposing the semiconductor testing device adjacent to the fixture device, the semiconductor testing device having a plurality of needles extending therefrom;
providing a first electrical charge to the fixture device to facilitate application of a first electrical charge to the needles, the first electrical charge having a first polarity; and
etching the needles with an etching device, the etching device having a second electrical charge of a second polarity, the second polarity being opposite the first polarity.

24. A method according to claim 23 wherein the semiconductor testing device is a probe card.

25. A method according to claim 24 wherein disposing the probe card comprises securing the probe card to the fixture device such that the probe card is in contact with the pin sections of the fixture device.

26. A method according to claim 25 wherein securing the probe card comprises placing the probe card in latches extending from the fixture device, and engaging the latches to releasably secure the probe card to the fixture device.

27. A method according to claim 23 wherein providing a first electrical charge comprises connecting a power supply to the fixture device to provide a first electrical charge to the fixture device.

28. A method according to claim 27 wherein connecting a power supply comprises connecting a wire from a negative voltage source of the power supply to an electrically conductive element extending from the base portion of the fixture device.

29. A method according to claim 27 wherein the second electrical charge is provided by connecting the power supply to the etching device.

30. A method according to claim 29 wherein connecting the power supply to the etching device comprises connecting a wire from a positive voltage source of the power supply to a metallic ring positioned about the etching device.

31. A method according to claim 27 wherein the power supply is a DC power supply.

32. A method according to claim 27 wherein the power supply is an AC power supply.

33. A method according to claim 23 wherein etching the needles with an etching device comprises etching the needles with an etching brush.

34. A method according to claim 33 wherein the etching brush includes etching liquid comprised of an electrolyte and de-ionized water.

35. A method according to claim 34 wherein the electrolyte is sodium hydroxide (NaOH) or potassium hydroxide (KOH).

36. A method according to claim 34 wherein the etching liquid is 1 unit electrolyte for every 10 units of de-ionized water.

37. A method for performing plating operations on a semiconductor testing device, comprising:
providing a fixture device having a base portion, and a plurality of pin sections extending from the base portion;
disposing the semiconductor testing device adjacent to the fixture device, the semiconductor testing device having a pad formed thereon;
providing a first electrical charge to the fixture device to facilitate a first electrical charge to the pad, the first electrical charge having a first polarity; and
plating the pad with a plating device, the plating device having a second electrical charge of a second polarity, the second polarity being opposite the first polarity.

38. A method according to claim 37 wherein the semiconductor testing device is a probe card.

39. A method according to claim 38 wherein disposing the probe card comprises securing the probe card to the fixture device such that the probe card is in contact with the pin sections of the fixture device.

40. A method according to claim 39 wherein securing the probe card comprises placing the probe card in latches extending from the fixture device, and engaging the latches to releasably secure the probe card to the fixture device.

41. A method according to claim 37 wherein providing a first electrical charge comprises connecting a power supply to the fixture device to provide a first electrical charge to the fixture device.

42. A method according to claim 41 wherein connecting a power supply comprises connecting a wire from a negative voltage source of the power supply to an electrically conductive element extending from the base portion of the fixture device.

43. A method according to claim 41 wherein the second electrical charge is provided by connecting the power supply to the plating device.

44. A method according to claim 43 wherein connecting the power supply to the plating device comprises connecting a wire from a positive voltage source of the power supply to a metallic ring positioned about the plating device.

45. A method according to claim 37 wherein plating the pad with a plating device comprises plating the pad with a plating pen.
